(19) United States
(12) Patent Application Publication
(10) Pub. No.: US 2012/0138972 A1
(43) Pub. Date: Jun. 7, 2012

(54) ARRAY SUBSTRATE AND A METHOD FOR FABRICATING THE SAME AND AN ELECTRONIC PAPER DISPLAY

(75) Inventors: Wenbo LI, Beijing (CN); Gang WANG, Beijing (CN); Zhuo ZHANG, Beijing (CN)

(73) Assignee: BOE TECHNOLOGY GROUP CO., LTD., Beijing (CN)

(21) Appl. No.: 13/308,752

(22) Filed: Dec. 1, 2011

(30) Foreign Application Priority Data
Dec. 3, 2010 (CN) 201010579460.6

(51) Int. Cl. H01L 33/62

(52) U.S. Cl. 257/88; 438/34; 438/197; 257/E33.062

(57) ABSTRACT

The present disclosure discloses a method for fabricating an array substrate comprising: depositing a source/drain metallic film on a first base substrate, and forming a source electrode, a drain electrode and a data line; sequentially depositing a semiconductor layer film, a gate insulating layer film and a gate metallic film on the first base substrate, and forming a semiconductor layer, a gate insulating layer, a gate electrode and a gate line; depositing a gate protection layer film on the first base substrate, and forming a gate protection layer and a through hole, wherein the through hole is formed on the gate protection layer corresponding to the drain electrode to expose a portion of the drain electrode; and depositing a pixel electrode film on the first base substrate, and forming a pixel electrode, wherein the pixel electrode is connected to the drain electrode via the through hole.

### BACKGROUND

Embodiments of the present disclosure relates to an array substrate and a method for fabricating the same and an electronic paper display.

The electronic paper display is a new type display apparatus having advantages of both display and paper. The electronic paper display presents a display effect close to that of a paper, and has advantages of flexible display, portability, erasibility, low power consumption and so on.

An active electronic paper display mainly comprises an upper substrate (an electrophoresis substrate), an electronic ink layer (display medium) and a lower substrate (an array substrate), usually employing a bottom gate inverted-staggered structure, and is formed by directly attaching the upper substrate coated with electrophoresis particles and the array substrate. Wherein the electronic ink layer comprises white pigment particles, which have excellent reflectivity and is used to display in bright state, and black particles, which have excellent absorbility and is used to display in dark state. The active electronic paper display usually employs a reflective-type array substrate, and displays images by reflecting ambient light without a backlight source. A typical structure of the conventional reflective-type array substrate comprises a base substrate, data lines and gate lines crossing with each other and formed on the base substrate, and pixel units arrayed in a matrix form surrounded and defined by data lines and gate lines, each pixel unit comprising a thin film transistor (hereafter, referred to as TFT) switch and a pixel electrode, wherein a TFT switch comprises a gate electrode connected to the gate line, a source electrode connected to the data line, a drain electrode connected to the pixel electrode and an active layer formed between the source/drain electrodes and the gate electrode. The base substrate generally further comprises a common electrode line for inputting a common voltage to a common electrode. In a typical structure of the array substrate, the channel within a TFT region is formed at a relatively top level without a blocking layer thereon.

Since the conventional electronic paper display mainly employs a bottom gate inverted-staggered structure, in which a black matrix can not be formed in the upper substrate assembling with the array substrate to overlap the TFT region on the array substrate. Thus, the channel in the TFT region may be irradiated by the external ambient light passing through the electrophoresis particle layer, resulting in a relatively large leakage current, in which case a crosstalk upon display is caused and a contrast of the electronic paper display is degraded. In the prior art, the problem is solved by forming a light blocking layer in the TFT region with a special material. The structure of the array substrate formed according to the above solution is shown in FIG. 1, which comprises a base substrate 1 having gate lines (not shown)formed thereon, a gate electrode 3, a gate insulating layer 4, a semiconductor layer 61, a doped semiconductor layer 62, a source electrode 7, a drain electrode 8, data lines (not shown), a passivation layer 9, a light blocking layer 12, a through hole 10 and a pixel electrode 11. Following the formation of the passivation layer 9, the light blocking layer 12 is formed by coating black organic photosensitive material on the base substrate 1 and then forming the through hole 10 by etching the black organic photosensitive material through exposure and etching processes; and the pixel electrode 11 is connected to the drain electrode 8 through the through hole 10.

The difference between the above-described array substrate and a typical structure lies in the added light blocking layer, which solves the problem of a leakage current generated in the TFT region due to being irradiated. However, those skilled in the art will be understood that the solution of incorporating a light blocking layer not only needs a special black organic photosensitive material formed as a light blocking layer, but also has strict requirements of the concentration, stiffness and flatness on the material during manufacturing, as a result, this solution can not be widely distributed and applied. That is, a problem existing in the electronic paper display employing a bottom gate type inverted-staggered structure that the display performance is degraded due to the leakage current generated by ambient light irradiated on the TFT region still needs to be solved.

### SUMMARY

According to an embodiment, a method for manufacturing an array substrate comprises the following steps in order: depositing a source/drain metallic film on a first base substrate, and forming patterns comprising a source electrode, a drain electrode and a data line through a patterning process; sequentially depositing a semiconductor layer film, a gate insulating layer film and a gate metallic film on the first base substrate, and forming patterns comprising a semiconductor layer, a gate insulating layer, a gate electrode and a gate line through a patterning process; depositing a gate protection layer film on the first base substrate, and forming patterns comprising a gate protection layer and a through hole through a patterning process, wherein the through hole is formed on the gate protection layer corresponding to the drain electrode to expose a portion of the drain electrode; and depositing a pixel electrode film on the first base substrate, and forming patterns comprising a pixel electrode by a patterning process, wherein the pixel electrode is connected to the drain electrode via the through hole.

According to another embodiment of the disclosure, an array substrate comprises a first base substrate having gate lines and data lines formed thereon, the gate lines and the data lines crossing with each other to surround and define pixel units, each pixel unit comprising a TFT switch and a pixel electrode, the TFT switch comprising a gate electrode, a source electrode, a drain electrode and a semiconductor layer; wherein: the source electrode, the drain electrode and the data line are formed on the first base substrate; the semiconductor layer comprises a first portion disposed corresponding to the gate electrode and formed between the source electrode and the drain electrode and connected to the source electrode and the drain electrode, and a second portion disposed corresponding to the gate line; the gate insulating layer is formed on the semiconductor layer; the gate electrode and the gate line are formed on the gate insulating layer, and the semiconductor layer, the gate insulating layer, the gate electrode and the gate line are synchronously formed; the gate protection layer is formed over the gate electrode; and the pixel electrode is connected to the drain electrode through the through hole penetrating the gate protection layer.

According to further another embodiment of the disclosure, an electron paper display, comprising the above-described array substrate and an upper substrate disposed oppositely to the array substrate with display medium interposed therebetween.

Further scope of applicability of the present disclosure will become apparent from the detailed description given hereinafter. However, it should be understood that the detailed description and specific examples, while indicating preferred embodiments of the disclosure, are given by way of illustration only, since various changes and modifications within the spirit and scope of the disclosure will become apparent to those skilled in the art from the following detailed description.

### BRIEF DESCRIPTION OF THE DRAWINGS

The present disclosure will become more fully understood from the detailed description given hereinafter and the accompanying drawings which are given by way of illustration only, and thus are not limitative of the present disclosure and wherein:

FIG. 1 is a schematic sectional structural view of a conventional array substrate incorporating a light blocking layer;

FIG. 2A is a schematic structural side view of the array substrate comprising patterns of a doped semiconductor layer, a source electrode, a drain electrode and a data line formed in a method for manufacturing the array substrate according to an embodiment of the disclosure;

FIG. 2B is a schematic structural side view of the array substrate comprising patterns of a semiconductor layer, a gate insulating layer, a gate line and a gate electrode formed in a method for manufacturing the array substrate according to an embodiment of the disclosure;

FIG. 2C is a schematic structural side view of the array substrate comprising patterns of a gate protection layer and a through hole formed in the method for manufacturing the array substrate according to an embodiment of the disclosure;

FIG. 2D is a schematic structural side view of the array substrate comprising patterns of a pixel electrode formed in the method for manufacturing the array substrate according to an embodiment of the disclosure;

FIG. 2E is partial schematic top structural view of the array substrate formed in the method for manufacturing the array substrate according to an embodiment of the disclosure;

FIG. 3A is a partial schematic top view of the array substrate comprising a doped semiconductor layer, a source electrode, a drain electrode, a data line and a storage electrode formed by the method for manufacturing the array substrate according to another embodiment of the disclosure;

FIG. 3B is a schematic structural side view taken along A-A line in FIG. 3A;

FIG. 3C is a partial schematic structural top view of the array substrate formed in the method for manufacturing the array substrate according to another embodiment of the disclosure;

FIG. 3D is a schematic structural side view taken along A-A line in FIG. 3C;

FIG. 4A is a partial schematic structural top view of the array substrate formed by the method for manufacturing the array substrate according to still another embodiment of the disclosure; and

FIG. 4B is a schematic structural side view taken along A-A line in FIG. 4A.

### DETAILED DESCRIPTION

The technical solution of the embodiments of the disclosure will be fully and completely described hereafter by incorporating attached figures of embodiments of the disclosure such that a purpose, technical solutions and advantages thereof are clearer, and it is obvious that the described embodiments are only a part of embodiments of the disclosure rather than whole embodiments thereof. Based on embodiments of the disclosure, all the other embodiments obtained by the skilled in the art without any creative work are all within the scope claimed by the present disclosure.

### Embodiment 1

According to an embodiment of the disclosure, a method for manufacturing the array substrate comprises the following steps.

Step 201, a source/drain metallic film is deposited on a first base substrate, and patterns including a source electrode, a drain electrode and a data line are formed by a patterning process.

Particularly, a source/drain metallic film can be deposited on the first base substrate by a sputtering process, and wherein the source/drain metallic film may be formed of metals such as aluminum (Al), molybdenum (Mo), neodymium (Nd) and so on; next, patterns such as a source electrode, a drain electrode and a data line and so on may be formed by a patterning process. The region for forming a TFT channel is located between the source electrode and the drain electrode.

Step 202, a semiconductor layer film, a gate insulating layer film and a gate metallic film is sequentially deposited on the first base substrate having the above-described patterns formed thereon, and patterns including a semiconductor layer, a gate insulating layer, a gate electrode and a gate line are formed by a patterning process.

In this case, the semiconductor layer is formed between the source electrode and the drain electrode, and electrically connects with the source electrode and the drain electrode, respectively. The semiconductor layer is an active layer.

Particularly, the semiconductor layer film is deposited on the first base substrate having the source electrode, the drain electrode and the data line formed thereon by a sputtering method. Next, the gate insulating layer film is deposited for example by a plasma enhanced chemical vapor deposition (referred to PECVD) method, followed by depositing the gate metallic film such as Mo by using a sputtering method. Next, patterns such as the semiconductor layer, the gate insulating layer, the gate electrode and the gate line and so on are formed by patterning the above described films. In this case, the gate electrode is formed on the semiconductor layer, that is to say, corresponding to the TFT channel. In the present embodiment, the gate electrode shields the TFT channel. The gate insulating layer covers the semiconductor layer to insulate the semiconductor layer from the gate electrode.

Step 203, a gate protection layer film is deposited on the first base substrate having the aforesaid patterns formed thereon, and patterns including a gate protection layer and a through hole are formed by a patterning process. The through hole is formed on the gate protection layer corresponding to the drain electrode to expose a portion of the drain electrode;

Particularly, the gate protection layer film is deposited for example by a PECVD method; then the gate protection layer and the through hole are formed by a patterning process. The gate protection layer is mainly used to insulate the gate electrode from other patterns on the gate electrode so as to protect the gate electrode. In the present embodiment, the through hole penetrates through the gate protection layer to expose a portion of the drain electrode so as to connect the drain electrode with a pixel electrode to be formed in the next step. To make the pixel electrode and the drain electrode sufficiently contact with each other, the gate protection layer at a corresponding position can be over-etched properly.

Step 204, patterns including the pixel electrode are formed by depositing and patterning a pixel electrode film on the first base substrate formed with the aforesaid patterns. The pixel electrode is connected to the drain electrode through the through hole.

Particularly, the pixel electrode film is deposited by a sputtering method, and then the pixel electrode is foiined by a patterning process. The pixel electrode includes a portion deposited in the through hole for connecting with the drain electrode.

The patterning process involved in the present embodiment generally includes operations such as coating photoresist, exposing and developing, etching and removing the photoresist and so on. The patterning process in an embodiment of the disclosure is described with the patterning process in the step 203 as an example. The patterning process in the step 203 comprises the following steps.

Step 2031, photoresist is coated on the gate protection layer film;

Step 2032, the photoresist is exposed and developed by using a mask to form a photoresist pattern including a region with the photoresist completely removed and a photoresist-completely-retained region. The photoresist-completely-removed region corresponds to a region where the through hole is formed, and the photoresist-completely-retained region corresponds to other regions.

Step 2033, the gate protection layer film at the region with the photoresist completely removed is dry etched to form the through hole and the gate protection layer.

An array substrate having a top gate type structure is formed by the above described depositing and patterning processes according to the manufacturing method for an array substrate according to the present embodiment, in which the gate electrode is located above the TFT channel and can block the irradiation of the ambient light to the TFT channel. Thus, a leakage current generated in the TFT channel due to the light irradiation may be prevented and an influence of the leakage current on the display performance of the array substrate may be decreased. Accordingly, the display quality of the array substrate may be improved. Further, in the present embodiment, the semiconductor layer, the gate insulating layer, the gate electrode and the gate line are simultaneously formed by a single patterning process, that is, the semiconductor layer, the gate insulating layer, the gate electrode and the gate line are formed synchronously, which simplifies the manufacturing process of an array substrate and increases the manufacturing efficiency of the array substrate and reduces the manufacturing cost.

### Embodiment 2

The array substrate formed by the manufacturing method according to the present embodiment is an array substrate of a reflective type active display (for example, an electronic paper display) based on and similar to that of the first embodiment, with the main difference therebetween lying in a doped semiconductor layer formed over the source electrode, the drain electrode and the data line in the present embodiment. The manufacturing method according to the present embodiment includes the following steps.

Step 301, a source/drain metallic film and a doped semiconductor layer film are deposited on a first base substrate, and patterns including a doped semiconductor layer, a source electrode, a drain electrode, and a data line are formed by a patterning process.

Particularly, the source/drain metallic film is deposited on the first base substrate by a sputtering process, and then the doped semiconductor layer film is deposited on the source/drain metallic film using a PECVD method. It is preferable that N+-a-Si is used as the material for the doped semiconductor layer. Then, patterns including a doped semiconductor layer, a source electrode, a drain electrode and a data line and so on are formed by a patterning process. The region for a TFT channel is located between the source electrode and the drain electrode.

The patterning process in the step 301 includes the following.

Step 3011, photoresist is coated on the doped semiconductor layer film.

Step 3012, the photoresist is exposed and developed using a mask to form a photoresist pattern including a region with the photoresist completely retained and a region with the photoresist completely removed;

Step 3013, the doped semiconductor layer film at the photoresist-completely-removed region is etched off by a dry etching process to form patterns including a doped semiconductor layer.

Step 3014, the source/drain metallic film at the photoresist-completely-removed region is etched off by a wet etching process to form patterns including a source electrode, a drain electrode and a data line.

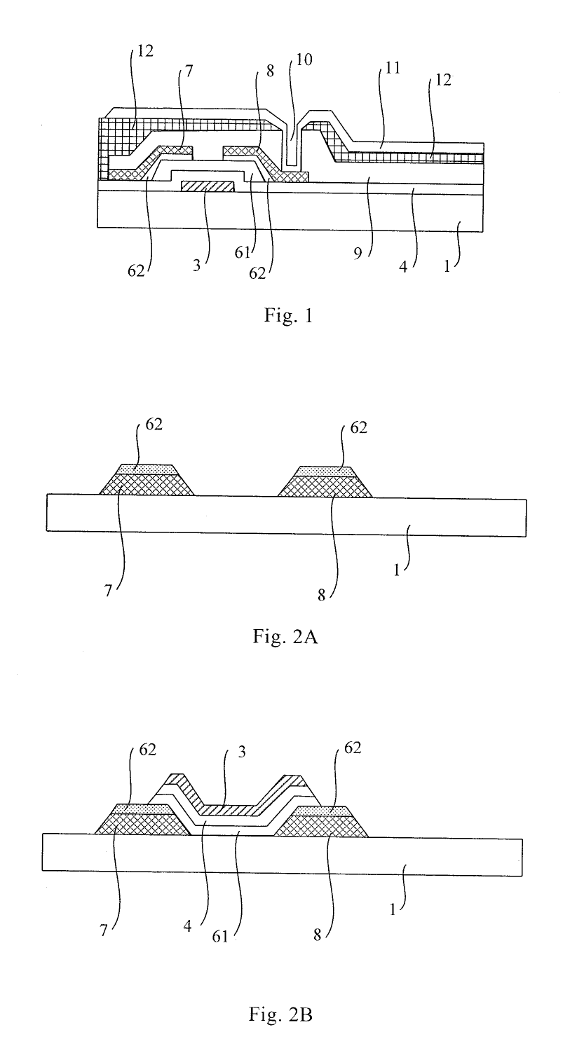

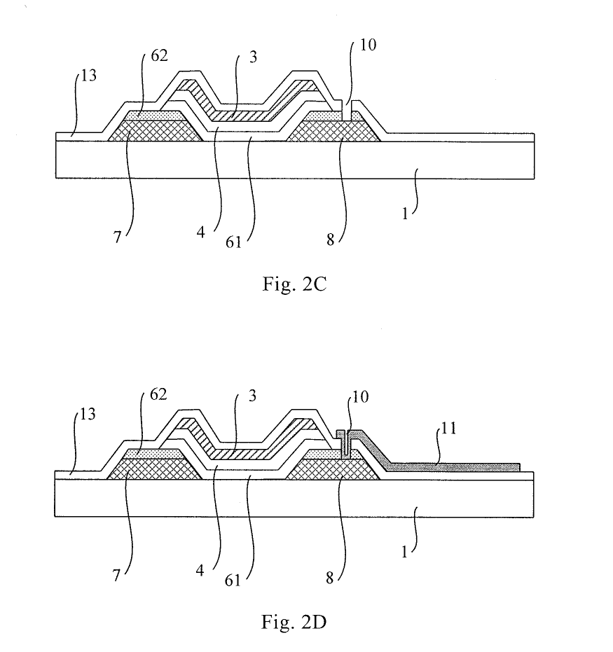

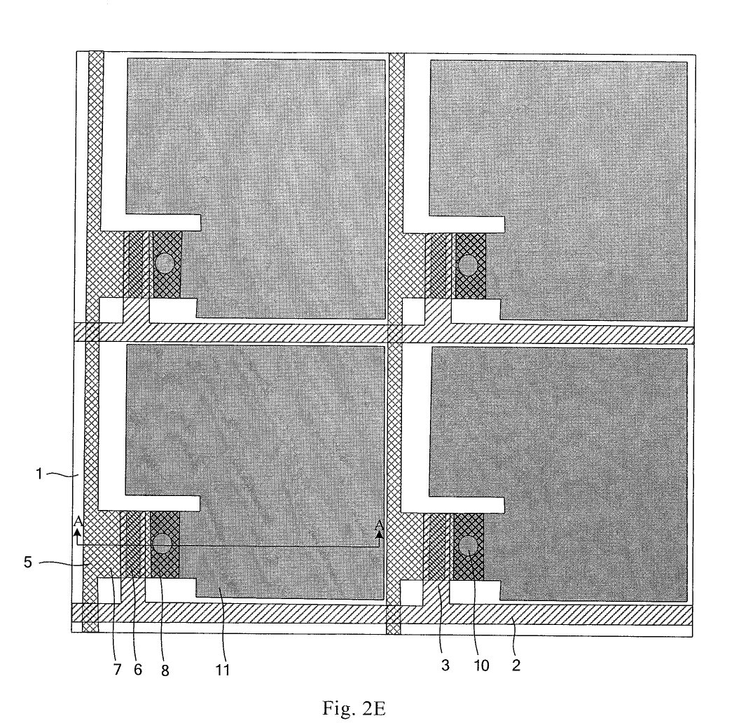

Through the above steps, the doped semiconductor layer is formed on the source electrode, the drain electrode and the data line, while the patterns including the source electrode, the drain electrode and the data line are formed. The side-viewed structure of the array substrate having the patterns including the doped semiconductor layer, the source electrode, the drain electrode and the data line formed by the aforesaid steps is shown in FIG. 2A, where a first base substrate 1, a source electrode 7, a drain electrode 8 and a doped semiconductor layer 62 are illustrated.

Step 302, a semiconductor layer film, a gate insulating layer film and a gate metallic film are sequentially deposited on the first base substrate formed with the aforesaid patterns, and patterns including a semiconductor layer, a gate insulating layer, a gate electrode and a gate line are formed by a patterning process.

Particularly, a semiconductor layer film is deposited on the first base substrate formed with the doped semiconductor layer, the source electrode, the drain electrode and the data line by a sputtering method, after which a gate insulating layer film is deposited by a PECVD method, and a gate metallic film such as Mo is deposited by using a sputtering method.

The patterning process in the step 302 including the following steps.

Step 3021, photoresist is coated on the gate metallic film.

Step 3022, a photoresist pattern including a photoresist-completely-removed region and a photoresist-completely-retained region is formed by exposing and developing the photoresist using a mask. The photoresist-completely-retained region corresponds to a TFT channel, that is, corresponds to the gate electrode and the gate line pattern. As the semiconductor layer, the gate insulating layer, the gate electrode and the gate line are formed synchronously by a same patterning process, they have a same shape. That is, the photoresist-completely-retained region corresponds to both the semiconductor layer and the gate insulating layer.

Step 3023, the gate metallic film at the photoresist-completely-removed region is etched by a wet etching process to form patterns including a gate electrode and a gate line gate line.

Step 3024, the gate insulating layer film and the semiconductor layer film at photoresist-completely-removed region are etched in sequence by a dry etching process to form patterns including the gate insulating layer and the semiconductor layer.

The aforesaid steps 3021-3024 may also be an example of the patterning process in step 202 of the first embodiment. The side viewed structure of the array substrate having the patterns including the semiconductor layer, the gate insulating layer, the gate line and the gate electrode formed by the aforesaid steps is shown in FIG. 2B, in which a first base substrate 1, a source electrode 7, a drain electrode 8, a doped semiconductor layer 62, a semiconductor layer 61 formed between the source electrode 7 and the drain electrode 8 and connected to the doped semiconductor layer 62, a gate insulating layer 4 on the semiconductor layer 61 and a gate electrode 3 and a gate line (not illustrated) corresponding to the gate insulating layer 4 and the semiconductor layer 61 are illustrated. The semiconductor layer 61 and the doped semiconductor layer 62 act as an active layer (as shown in FIG. 2B) together. The doped semiconductor layer 62 may increase contact conductance between the semiconductor layer 61 and the source electrode 7 and the drain electrode 8. The semiconductor layer 61 formed by the aforesaid solution includes two parts, that is, a first part disposed corresponding to the gate electrode 3 and a second part (not illustrated) disposed corresponding to the gate line.

When the contact conductance between the semiconductor layer 61 and the source and drain electrodes 7 and 8 is large enough, for example, when the semiconductor layer 61 employs an oxide semiconductor material, the doped semiconductor layer 62 may be omitted, and the semiconductor layer 61 may be directly connected to the source electrode 7 and the drain electrode 8.

Step 303, a gate protection layer film is deposited on the first base substrate formed with the aforesaid patterns, and patterns including a gate protection layer and a through hole are formed by a patterning process.

Particularly, the gate protection layer film may be formed on the first base substrate formed with the aforesaid patterns by a PECVD method.

The patterning process in the step 303 may include the following steps.

Step 3031, photoresist is coated on the gate protection layer film.

Step 3032, a photoresist pattern including a photoresist-completely-removed region and a photoresist-completely-retained region is formed by exposing and developing the photoresist with a mask. The photoresist-completely-removed region corresponds to a region where the through hole is formed, and the photoresist-completely-retained region corresponds to other regions.

Step 3033, a gate protection layer is formed by etching the gate protection layer film at the photoresist-completely-removed region by using a dry etching process.

Step 3034, the doped semiconductor layer at the photoresist-completely-removed region is etched by a wet etching process to form a through hole exposing a portion of the drain electrode. The doped semiconductor layer may be properly over-etched so that the drain electrode may sufficiently contact with a pixel electrode to be formed in the next step. If there does not exist a doped semiconductor layer structure, the patterning process in the step 303 does not include the step 3034, i.e., the through hole and the gate protection layer are formed by only etching the gate protection layer film corresponding to the photoresist-completely-removed region.

A side-viewed structure of the array substrate having patterns including the gate protection layer and the through hole formed by the aforesaid steps is shown in FIG. 2C, in which a first base substrate 1, a source electrode 7, a drain electrode 8, a doped semiconductor layer 62, a semiconductor layer 61 formed between the source electrode 7 and the drain electrode 8 and connected to the doped semiconductor layer 62, a gate insulating layer 4, a gate electrode 3 and a gate line (not illustrated), a gate protection layer 13 and a through hole 10 for exposing a portion of the drain electrode 8 are illustrated. The gate protection layer 13 is located over the gate electrode 3 and covers the whole first base substrate 1 except for the region where the through hole 10 is formed, and is mainly used to protect the gate electrode 3 and other patterns on the first base substrate 1.

In a conventional bottom gate type array substrate, the film layer which insulates a gate electrode and an upper pattern (that is, an active layer) from each other is the gate insulating layer, which covers the gate electrode. AS the thickness of the gate electrode is relatively large among patterns on the array substrate, in order to reduce the effect on patterns to be formed in subsequent processes, the requirement on the thickness of the gate insulating layer covering the gate electrode is strict. Generally, the thickness of the gate insulating layer is about 4000 Å. Therefore, in a conventional bottom gate type array substrate, it is not possible to increase a capacitance of the gate insulating layer to improve the charging ability of the TFT by decreasing the thickness of the gate insulating layer. Contrary to the prior art, an array substrate according to the present embodiment has a top gate type structure, in which the gate insulating layer film protecting the gate electrode by insulating the gate electrode from the active layer is deposited on the active layer so that the gate insulating layer covers the active layer. As the thickness of the active layer is relatively small among the patterns of the array substrate compared with the thickness of the gate electrode, in the present embodiment, the thickness of the gate insulating layer may be properly reduced to increase the capacitance per unit area of the gate insulating layer, which in turn improves the charging ability of the TFT, and enhances the display performance of the array substrate. The thickness of the gate insulating layer in the array substrate according to the present embodiment may be reduced by 20%-50% compared to that of the prior art (for example, 4000 Å). If it is 20% less than 4000 Å, the thickness of the gate insulating layer in the present embodiment is 3200 Å; if it is 50% less than 4000 Å, the thickness of the gate insulating layer in the present embodiment is about 2000 Å. The capacitance may be greatly increased if the thickness of the gate insulating layer is reduced as described above, which remarkably improves the performance of the array substrate.

Moreover, in the structure of a conventional bottom gate type array substrate, since the gate electrode is formed under other patterns of the array substrate, and the thickness of the gate electrode is relatively thick, the requirement on the thickness of the gate electrode is strict and the thickness of the gate electrode can not be increased arbitrarily in order to avoid influence on the patterns thereon. Therefore, it is relatively difficult for the bottom gate type array substrate to decrease a delay of a gate electrode signal by increasing the thickness of the gate electrode. On the contrary, according to the present embodiment, the gate metallic film is deposited on the other patterns, the gate electrode to be formed is almost over all patterns (except for the pixel electrode) on the array substrate, and the influence of the gate electrode on the patterns thereunder is farther less than that of a conventional bottom gate type structure. Therefore, the thickness of the gate electrode can be properly increased according to the present embodiment, so that the resistance of the gate electrode can be reduced, and the delay of the gate electrode signal can be decreased, thereby the display quality of the array substrate can be further improved. The thickness of the gate electrode according to the present embodiment may be larger than 2200 Å (which in the prior art is generally 2200 Å), or can be increased by 10%-30% compared to the typical thickness in the prior art. As the increased thickness of the gate electrode relates to factors such as the manufacturing process and the material, the thickness of the gate electrode in the present embodiment is only provided for reference, and the disclosure is not limited thereto.

Step 304, a pixel electrode film is deposited on the first base substrate formed with the aforesaid patterns, and patterns including a pixel electrode are formed by a patterning process, with the pixel electrode being connected to the drain electrode through the through hole.

Particularly, the pixel electrode film is deposited by a sputtering method. As the array substrate according to the present embodiment is an array substrate in a reflective type active display, in which the pixel electrode reflects ambient light to display an image, the material for the pixel electrode may be a transparent conductive material, for example indium tin oxide common (ITO) (a reflective layer may be further formed thereon), or a non-transparent conductive material, for example metallic material having relatively small resistivity, to reduce the delay of the common electrode signal.

The patterning process in the step 304 includes the following steps.

Step 3041, photoresist is coated on the pixel electrode film;

Step 3042, the pixel electrode film is exposed and developed with a mask to form a photoresist pattern including a photoresist-completely-removed region and a photoresist-completely-retained region; wherein, the photoresist-completely-retained region corresponds to the pixel electrode pattern.

Step 3043, the pixel electrode film at the photoresist-completely-removed region is etched to form patterns including the pixel electrode. The pixel electrode includes a portion deposited in the through hole so as to be connected to the drain electrode.

The aforesaid steps 3041-3043 may also be an example of the patterning process in step 204 of the first embodiment. The side viewed structure of an array panel having the patterns including the pixel electrode formed by the aforesaid steps is shown in FIG. 2D, in which a first base substrate 1, a source electrode 7, a drain electrode 8, a doped semiconductor layer 62, a semiconductor layer 61 formed between the source electrode 7 and the drain electrode 8 and connected to the doped semiconductor layer 62, a gate insulating layer 4, a gate electrode 3 and a gate line (not illustrated), a gate protection layer 13, a through hole 10 and a pixel electrode 11 connected to the drain electrode 8 through the through hole 10 are illustrated. The array substrate according to the present embodiment is so completed, and a partial structural top view is shown in FIG. 2E.

It should be noted that the present embodiment further comprises a step of removing the residual photoresist (i.e., the photoresist at the photoresist-completely-retained region) in each patterning process after each pattern is formed. As it is commonly known in the art, the detail is omitted to simplify the description.

An array substrate having a top gate type structure in which the gate electrode is located over the TFT channel is formed through the manufacturing method for the array substrate according to the present embodiment, in which the gate electrode can block the irradiation of the ambient light to the TFT channel. Thus, the leakage current generated in the TFT channel due to the light irradiation may be prevent and the influence of the leakage current on the display quality of the array substrate may be decreased, thereby the display performance of the array substrate may be improved. In addition, according to the present embodiment, the semiconductor layer, the gate insulating layer, and the gate electrode are simultaneously formed by a single patterning process, by which the manufacturing process for the array substrate is simplified, the manufacturing efficiency of the array substrate is increased and the manufacturing cost is reduced. Further, as a result of the top gate type structure, the thickness of the gate insulating layer can be reduced, thereby the charging ability of the TFT can be increased. The thickness of the gate electrode may also be increased, so that a resistance of the gate electrode may be reduced, and the delay of the gate electrode signal may be decreased, which further improves the performance of the array substrate.

### Embodiment 3

The present embodiment may be based on or similar to the first embodiment or the second embodiment, and for example, may be based on the second embodiment, with the difference therebetween lying in that a storage capacitor is formed according to the present embodiment while patterns including a doped semiconductor layer, a source electrode, a drain electrode and a data line are formed. Patterns including a doped semiconductor layer, a source electrode, a drain electrode, a data line and a storage electrode are formed through a patterning process similar to that of step 301, which includes the following steps.

Step 4011, photoresist is coated on the doped semiconductor layer film.

Step 4012, a photoresist pattern including a photoresist-completely-removed region and a photoresist-completely-retained region by exposing and developing the photoresist with a mask. The photoresist-completely-retained region corresponds to patterns of the source electrode, the drain electrode, the data line and the storage electrode, and the photoresist-completely-removed region corresponds to other regions.

Step 4013, the doped semiconductor layer film at the photoresist-completely-removed region is etched off by a dry etching process to form patterns including a doped semiconductor layer.

Step 4014, the source/drain metallic film at the photoresist-completely-removed region is etched off by a wet etching process to form patterns including a source electrode, a drain electrode, a data line and a storage electrode. That is, in the present embodiment, the storage electrode is formed while forming the source electrode, the drain electrode and the data line.

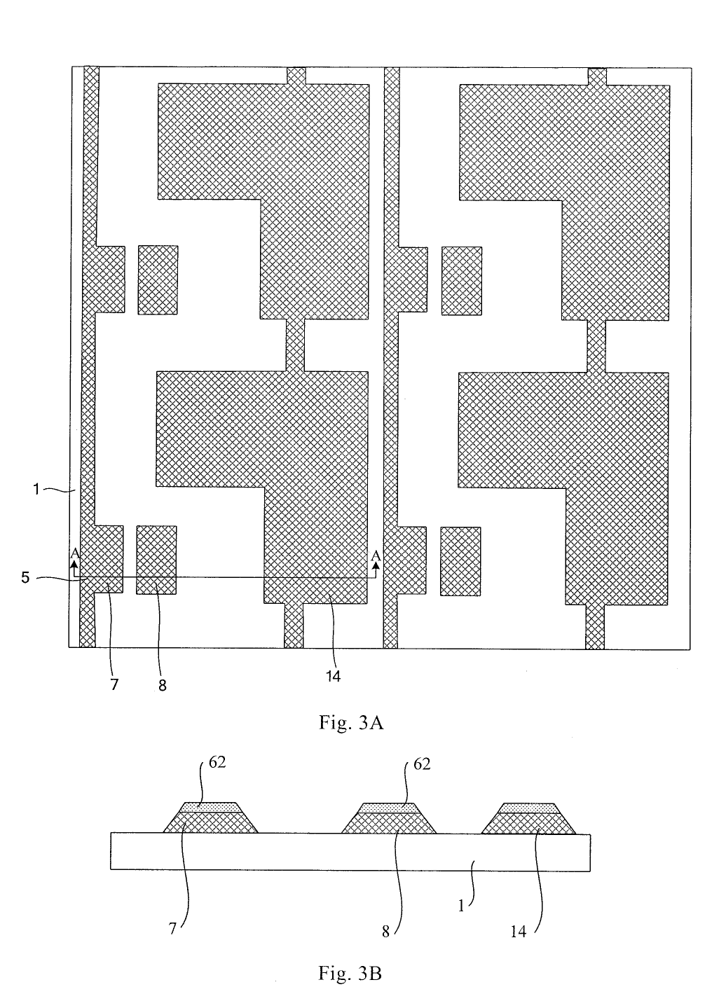

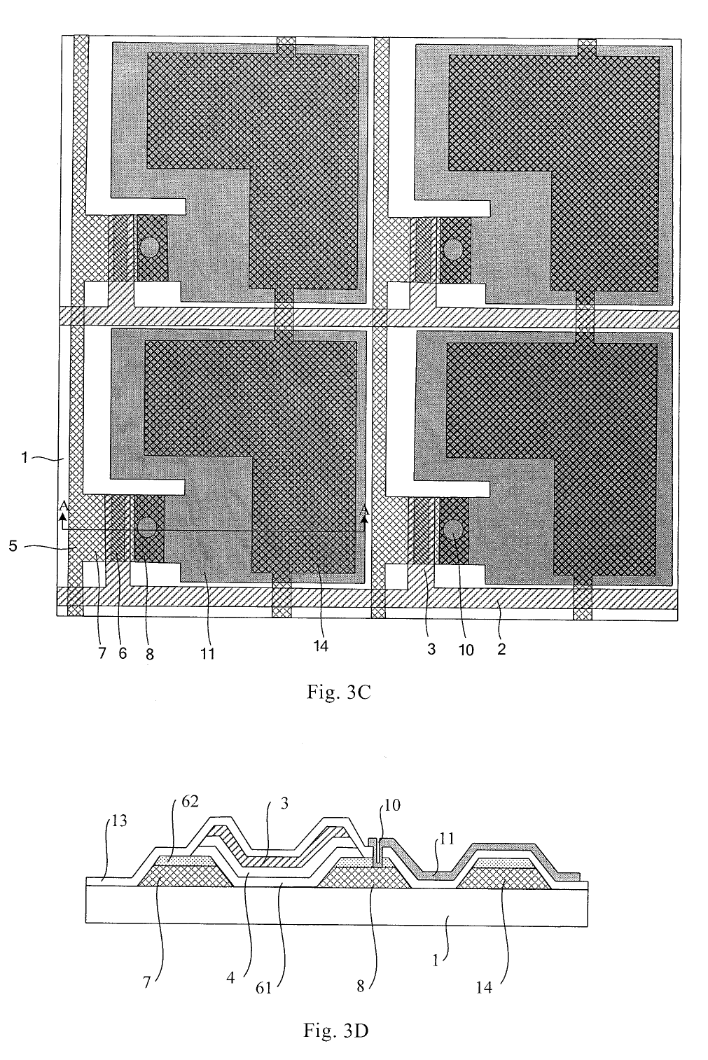

If based on the first embodiment, the aforesaid technical solution requires forming the storage electrode during the etching process of the step 201. FIG. 3A is a partial schematic top view of the array substrate including a doped semiconductor layer, a source electrode, a drain electrode, a data line and a storage electrode formed by the method for manufacturing the array substrate according to the third embodiment of the disclosure, FIG. 3B is a schematic structural side view taken along A-A line in FIG. 3A. FIGS. 3A and 3B show an exemplary partial structure of the storage electrode 14, where the lead of the storage electrode 14 is parallel to the data line. The shape of the storage electrode 14 may be adaptively modified according to the teaching of the present embodiment by the skilled in the art. It should be noted that FIG. 3A only shows the reference numerals of the source electrode, the drain electrode and the data line, without showing the doped semiconductor layer, since the doped semiconductor and the source electrode, the drain electrode and the data line are synchronously formed and the these patterns are overlapped with each other. The structure of the doped semiconductor layer is shown in FIG. 3B.

In the present embodiment, the storage electrode and the source electrode, the drain electrode and the data line are formed on the first base substrate at the same time, and a separate manufacturing process for forming a storage electrode is not needed. Accordingly, a manufacturing process for the array substrate is simplified, and the manufacturing cost is reduced. Furthermore, when the array substrate to be formed is an array substrate with a reflective type structure, the storage electrode does not have a negative effect on the aperture ratio of the array substrate, since the storage electrode is disposed under the pixel electrode and does not shield the pixel electrode. In this case, the area of the storage electrode may be properly increased to increase the storage capacitance while taking account of conductive patterns such as the source electrode and the drain electrode. It is known from the electrical characteristic of the TFT that by increasing the storage capacitance, the coupling capacitance effect between the data line, the gate line and the pixel electrode can be reduced, a kickback voltage of the pixel electrode may be effectively reduced, and a retention rate of the pixel electrode voltage may be improved, and the display quality of the array substrate may be further improved. That is, the solution according to the present embodiment has an advantage that the display quality of the array substrate may be further improved by increasing the storage capacitance.

Other steps may refer to the description for the second embodiment. FIG. 3C is a partial schematic structural top view of the array substrate finally completed according to the present embodiment. FIG. 3D is a schematic structural side view taken along a line A-A in FIG. 3C.

### Embodiment 4

The present embodiment may be achieved in a manner similar to or based on the first embodiment or the second embodiment. For example, suppose the present embodiment is based on the second embodiment, the difference therebetween lies in that a storage electrode is formed in the present embodiment while patterns including a semiconductor layer, a gate insulating layer, a gate electrode and a gate line are formed. Patterns including a semiconductor layer, a gate insulating layer, a gate electrode, a gate line and a storage electrode are formed through a patterning process similar to that of step 302, which includes the following steps.

Step 5011, photoresist is coated on the gate metallic film;

Step 5012, the photoresist is exposed and developed with a mask to form a photoresist pattern having a photoresist-completely-retained region and a photoresist-completely-removed region. The photoresist-completely-retained region corresponds to a TFT channel and a storage electrode, that is, corresponds to patterns of a semiconductor layer, a gate insulating layer, a gate electrode, a gate line and a storage electrode, and the photoresist-completely-removed region corresponds to other regions.

Step 5013, the gate metallic film at the photoresist-completely-removed region is etched by a wet etching process to faun patterns including a gate electrode, a gate line and a storage electrode.

Step 5014, the gate insulating layer film and the semiconductor layer film at the photoresist-completely-removed region are etched in sequence by a dry etching process to form patterns including the gate insulating layer and the semiconductor layer. The storage electrode has the gate insulating layer film and the semiconductor layer film formed thereunder.

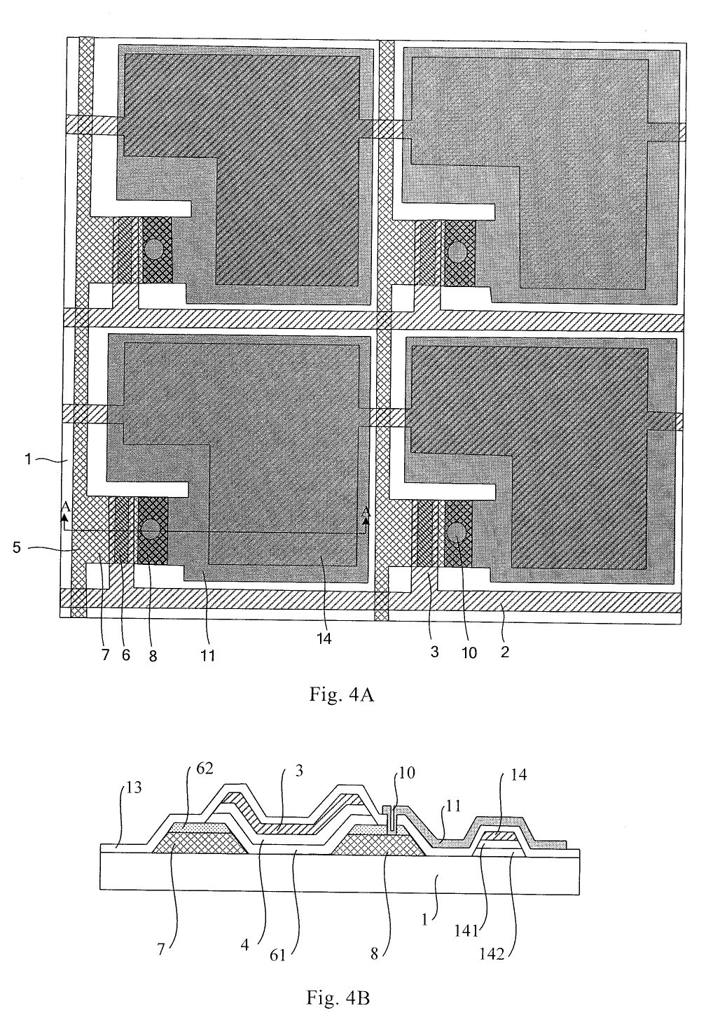

The other steps may refer to the description of the above described embodiment. FIG. 4A is a partial structural top view of the array substrate finally formed according to the present embodiment. FIG. 4B is a side-viewed structure of the array substrate taken along a line A-A in FIG. 4A. The array panel according to the present embodiment comprises a first base substrate 1, a source electrode 7, a drain electrode 8, a doped semiconductor layer 62, a semiconductor layer 61 formed between the source electrode 7 and the drain electrode 8 and connected to the doped semiconductor layer 62, a gate insulating layer 4, a gate electrode 3, a storage electrode 14, a gate protection layer 13, a through hole 10 and a pixel electrode 11 connected to the drain electrode 8 through the through hole 10. A gate insulating layer film 141 and a semiconductor layer film 142 are disposed under the storage electrode 14.

In the present embodiment, the storage electrode is synchronously formed of the same material as the gate electrode and the gate line in the patterning process for forming the semiconductor layer, the gate insulating layer, the gate electrode and the gate line, where a separate manufacturing process for forming a storage electrode is omitted. Therefore, the manufacturing process for the array substrate is simplified, and the manufacturing cost is reduced. Furthermore, when the array substrate to be formed is an array substrate with a reflective type structure, the storage electrode does not have a negative effect on the aperture ratio of the array substrate, since the storage electrode is disposed under the pixel electrode and it does not shield the pixel electrode. Thus, the storage electrode will not influence the aperture ratio of the array substrate. In this case, the area of the storage electrode may be properly increased to increase the storage capacitance on taking account of conductive patterns such as the source electrode and the drain electrode. It is known from the electrical characteristics of the TFT that by increasing the storage capacitance, the coupling capacitance effect between the data line, the gate line and the pixel electrode may be weakened, a kickback voltage of the pixel electrode may be effectively reduced, and a retention rate of the pixel electrode voltage may be improved, thereby the display quality of the array substrate may be further improved. That is, the solution according to the present embodiment has an advantage that the display quality of the array substrate may be further improved by increasing the storage capacitance.

### Embodiment 5

The fifth embodiment of the disclosure provides an array substrate. Referring to FIGS. 2D and 2E, the array substrate includes a first base substrate, gate lines 2 and data lines 5 crossed with each other formed thereon, and a plurality of pixel units surrounded and defined the crossing gate lines 2 and data lines 5. Each pixel unit includes a pixel electrode 11 and a TFT switch. The TFT switch includes a gate electrode 3, a source electrode 7, a drain electrode 8 and an active layer 6. The active layer 6 is located between the gate electrode 3, the source electrode 7 and the drain electrode 8. The gate electrode 3 is connected to the gate line 2, the source electrode 7 is connected to the data line 5, and the pixel electrode 11 is connected to the drain electrode 8.

The source electrode 7, the drain electrode 8 and the data line 5 are formed on the first base substrate 1. The active layer 6 includes a semiconductor layer 61, which includes a first portion disposed between the source electrode 7 and the drain electrode 8 corresponding to the gate electrode 3 and connected to the source electrode 7 and the drain electrode 8, and a second portion disposed corresponding to the gate line. If the material employed can meet the conductive requirements between the semiconductor layer 61 and the source electrode 7 and the drain electrode 8, for example, when the semiconductor layer 61 is formed of an oxide semiconductor material, the active layer 6 may only comprise the semiconductor layer 61. When the employed material can not meet the conductive requirements between the semiconductor layer 61 and the source electrode 7 and the drain electrode 8, the active layer 6 may also comprise the doped semiconductor layer 62. The gate insulating layer 4 is formed on the active layer 6. The gate electrode 3 and the gate line 2 are formed on the gate insulating layer 4. In an array substrate according to the present embodiment, the semiconductor layer 61, the gate insulating layer 4, the gate electrode 3 and the gate line 2 are synchronously formed, that is, the semiconductor layer 61, the gate insulating layer 4, the gate electrode 3 and the gate line 2 are simultaneously formed through a same patterning process. The gate protection layer 13 is formed on the gate electrode 3. The pixel electrode 13 is connected to the drain electrode 8 through the through hole 10 extending through the gate protection layer 13.

The array substrate according to the present embodiment has a top gate type structure, in which the gate electrode is located over an active layer or a TFT channel and may block the irradiation of the ambient light to the TFT channel, so that leakage current generated in the TFT channel due to the light illumination may be avoided and the influence of the leakage current on the display quality of the array substrate may be reduced. Therefore, the array substrate according to the present embodiment has excellent display quality. In addition, the semiconductor layer, the gate insulating layer and the gate electrode and the gate line in the present embodiment are formed through a same patterning process, that is, they are synchronously formed, which simplifies the manufacturing process for the array substrate, and reduces the manufacturing cost.

The active layer 6 in the array substrate according to the present embodiment includes a semiconductor layer 61 and a doped semiconductor layer 62. The doped semiconductor layer 62 may increase the contact conductance between the semiconductor layer 61 and the source electrode 7 and the drain electrode 8. The doped semiconductor layer 62 and the source electrode 7, the drain electrode 8 and the data line 5 are formed by a same patterning process and are formed on the source electrode 7 and the drain electrode 8. The semiconductor layer 61 is formed on the doped semiconductor layer 62. A first portion of the semiconductor layer 61 is electrically connected to the source electrode 7 and the drain electrode 8 through the doped semiconductor layer 62, respectively. In this case, the through hole 10 needs to extend through the gate protection layer 13 and the doped semiconductor layer 62 simultaneously to expose a portion of the drain electrode 8.

In the configuration of a conventional bottom gate type array substrate, the film layer which insulates the gate electrode and an upper pattern (that is, an active layer) from each other is the gate insulating layer. The gate insulating layer covers the gate electrode from upside. The thickness of the gate electrode is relatively thick among the patterns of the array substrate. In order not to influence patterns to be formed in the subsequent process, requirement on the thickness of the gate insulating layer covering the gate electrode is strict. Generally, the thickness of the gate insulating layer is about 4000 Å. Therefore, in the conventional bottom gate type array substrate, it is not possible to increase a capacitance of the gate insulating layer to improve the charging ability of the TFT by decreasing the thickness of the gate insulating layer. Contrary to the prior art, the array substrate according to the present embodiment has a top gate type structure, in which the gate insulating layer film protecting the gate electrode by insulating the gate electrode from the active layer is deposited on the active layer so that the gate insulating layer covers the active layer. As the thickness of the active layer is relatively less than the thickness of the gate electrode among the patterns of the array substrate, therefore, in the present embodiment, the thickness of the gate insulating layer may be properly reduced to increase the capacitance per unit area of the gate insulating layer, which in turn improves the charging ability of the TFT, and improves the display performance of the array substrate. According to a relationship between the thicknesses of typical active layer and gate electrode, the thickness of the gate insulating layer in the array substrate according to the present embodiment may be reduced by 20%-50% compared to that of the prior art (for example, 4000 Å). If it is 20% less than 4000 Å, the thickness of the gate insulating layer in the present embodiment is 3200 Å; if it is 50% less than 4000 Å, the thickness of the gate insulating layer in the present embodiment is about 2000 Å. The capacitance of the gate insulating layer may be greatly increased if the thickness of the gate insulating layer is reduced as described above, which remarkably improves the performance of the array substrate.

Moreover, in the structure of the conventional bottom gate type array substrate, the gate electrode is formed under other patterns of the array substrate, and the thickness of the gate electrode is relatively large, therefore, in order to avoid influence on the patterns thereon, requirement on the thickness of the gate electrode is strict and the thickness of the gate electrode can not be increased arbitrarily. In this case, it is difficult for the bottom gate type array substrate to decrease a delay of a gate electrode signal by increasing the thickness of the gate electrode. On the contrary, in the present embodiment, the gate metallic film is deposited on the other patterns, the gate electrode to be formed is located almost over all patterns (except the pixel electrode) on the array substrate, and thus the influence of the gate electrode on the patterns thereunder is much less than that in the conventional bottom gate type structure. Therefore, the thickness of the gate electrode can be properly increased according to the present embodiment, so that the resistance of the gate electrode can be reduced, and the delay of the gate electrode signal can be decreased, thereby the display quality of the array substrate can be further improved. The thickness of the gate electrode according to the present embodiment may be larger than 2200 Å (which in the prior art is generally 2200 Å), or can be increased by 10%-30% compared to the general thickness in the prior art. As an increase of the thickness of the gate electrode relates to factors such as the manufacturing process and the material, the thickness of the gate electrode in the present embodiment is only provided for reference, and the disclosure is not limited thereto.

It should be noted that the array substrate in the present embodiment can be fabricated by the manufacturing method for the array substrate provided in the aforesaid embodiments of the disclosure, but not limited thereto. The array substrate in the present embodiment can also be fabricated through other manufacturing processes.

### Embodiment 6

The sixth embodiment of the disclosure provides an array substrate, referring to FIGS. 3A-3C. On the basis of the fifth embodiment, the array substrate may act as an array substrate of a reflective type active display. The array substrate according to the present embodiment also includes a storage electrode 14. The storage electrode 14 may be formed of the same material as a source electrode 7, a drain electrode 8 and a data line 5 while they are formed. That is, the storage electrode 14 and the source electrode 7, the drain electrode 8 and the data line 5 may be synchronously formed and disposed at a same level in the array substrate of the present embodiment. The detailed forming method of the storage electrode of the array substrate may refer to the related description in the aforesaid third embodiment. The array substrate provided in the sixth embodiment may be applied to an electronic paper display.

In the present embodiment, the storage electrode and the source electrode, the drain electrode and the data line are concurrently formed on the first base substrate, where a separate manufacturing process for forming a storage electrode is omitted. Therefore, the manufacturing process for the array substrate is simplified, and the manufacturing cost is reduced. Furthermore, when the array substrate to be formed is an array substrate with a reflective type structure, the storage electrode does not have a negative effect on the aperture ratio of the array substrate, since the storage electrode is disposed under the pixel electrode and does not shield the pixel electrode. Thus, the area of the storage electrode may be properly increased to increase the storage capacitance on taking account of conductive patterns such as the source electrode and the drain electrode. It is known from the electrical characteristics of a TFT that by increasing the storage capacitance, the coupling capacitance effect between the data line, the gate line and the pixel electrode may be decreased, a kickback voltage of the pixel electrode may be effectively reduced, and a retention rate of the pixel electrode voltage may be improved. Accordingly, the display quality of the array substrate may be further improved. That is, the solution according to the present embodiment has an advantage that the display quality of the array substrate may be further improved by increasing the storage capacitance.

### Embodiment 7

The seventh embodiment of the disclosure provides an array substrate, referring to FIGS. 4A-4B. On the basis of the fifth embodiment, the array substrate may act as an array substrate of a reflective type active display. The array substrate of the present embodiment further includes a storage electrode 14. The storage electrode 14 may be formed at a same level synchronously as the gate electrode 3 and the gate line 2 with a same material as that of the gate electrode 3, during the patterning process for forming the semiconductor layer 61, the gate insulating layer 4 and the gate electrode 3. That is, the storage electrode 14 in the present embodiment may be formed synchronously at the same level as the gate electrode 3 and the gate line 2. A gate insulating layer film 141 and a semiconductor layer film 142 are disposed under the storage electrode 14. The detail forming method for the storage electrode of the array substrate may refer to the related description in the aforesaid fourth embodiment. The array substrate provided according to the sixth embodiment may be applied to an electronic paper display.

In the present embodiment, the storage electrode is synchronously formed of the same material as the gate electrode and the gate line in the patterning process for forming the semiconductor layer, the gate insulating layer, the gate electrode and the gate line, where a separate manufacturing process for forming the storage electrode is omitted. Therefore, the manufacturing process of the array substrate is simplified, and the manufacturing cost is reduced. Furthermore, when the array substrate to be formed is an array substrate with a reflective type structure, the storage electrode does not have a negative effect on the aperture ratio of the array substrate, since the storage electrode is disposed under the pixel electrode and it does not shield the pixel electrode. Thus, the area of the storage electrode may be properly increased to increase the storage capacitance on taking account of conductive patterns such as the source electrode and the drain electrode. It is known from the electrical characteristics of a TFT that by increasing the storage capacitance, a coupling capacitance effect between the data line, the gate line and the pixel electrode may be weakened, a kickback voltage of the pixel electrode may be effectively reduced, and a retention rate of the pixel electrode voltage may be improved. Accordingly, the display quality of the array substrate may be further improved. That is, the solution according to the present embodiment has an advantage that the display quality of the array substrate may be further improved by increasing the storage capacitance.

The array substrate according to aforesaid embodiments of the disclosure may be used as an array substrate in a reflective type active display. In this case, as the pixel electrode displays an image by reflecting ambient light, the material of the pixel electrode may be a transparent and conductive material, for example indium tin oxide common electrode (ITO) having a reflective layer formed thereon. Alternatively, the material of the pixel electrode may also be a non-transparent and conductive material, for example a metallic material having relatively small resistivity to reduce the delay of the common electrode signal.

### Embodiment 8

The eighth embodiment of the disclosure provides an electronic paper display, which includes any array substrate according to the aforesaid embodiments of the disclosure and an upper substrate disposed oppositely to the array substrate with display medium interposed therebetween.

Further, said upper substrate includes a second base substrate.

The upper substrate may be color filter substrate, in which case a common electrode, color resin and a black matrix may be formed on the second base substrate of the upper substrate. Alternatively, the upper substrate may not be a color filter substrate, in which case the second base substrate of the upper substrate may only have a common electrode formed thereon without the color resin and black matrix.

The material for the first base substrate of the array substrate and for the second base substrate of the upper substrate may be a flexible material.

The array substrate in an electronic paper display according to the present embodiment has a top gate type structure, in which the gate electrode is formed on the TFT channel. The irradiation of ambient light to the TFT channel may be blocked by the gate electrode, which may prevent leakage current generated in a TFT channel. Accordingly, an influence of leakage current on display performance of the array substrate is reduced, and the display quality of an active display such as an electronic paper display is improved.

The array substrate provided in the embodiments of the disclosure may be fabricated using the manufacturing method for the array substrate according to the embodiments of the disclosure, by which corresponding patterns may be formed.

And it should be noted that the above embodiments is only illustrated for describing the technical solution of the disclosure and not restrictive, and although the disclosure is described in detail by referring to the aforesaid embodiments, the skilled in the art should understand that the aforesaid embodiments can be modified and portions of the technical features therein may be equally changed, which does not depart from the spirit and scope of the technical solution of the embodiments of the disclosure.

What is claimed is:

1. A method for manufacturing an array substrate, comprising the following steps in order:
depositing a source/drain metallic film on a first base substrate, and forming patterns comprising a source electrode, a drain electrode and a data line through a patterning process;
sequentially depositing a semiconductor layer film, a gate insulating layer film and a gate metallic film on the first base substrate, and forming patterns comprising a semiconductor layer, a gate insulating layer, a gate electrode and a gate line through a patterning process;
depositing a gate protection layer film on the first base substrate, and forming patterns comprising a gate protection layer and a through hole through a patterning process, wherein the through hole is formed on the gate protection layer corresponding to the drain electrode to expose a portion of the drain electrode; and
depositing a pixel electrode film on the first base substrate, and forming patterns comprising a pixel electrode by a patterning process, wherein the pixel electrode is connected to the drain electrode via the through hole.

2. The method according to claim 1, further comprising depositing a doped semiconductor layer film after depositing the source/drain metallic film on the first base substrate and before forming the patterns comprising the source electrode, the drain electrode and the data line by the patterning process;
the forming of patterns comprising the source electrode, the drain electrode and the data line by the patterning process comprising:
coating photoresist on the doped semiconductor layer film;
exposing and developing the photoresist with a mask to form a photoresist pattern comprising a photoresist-completely-retained region and a photoresist-completely-removed region, the photoresist-completely-retained region corresponds to patterns of the source electrode, drain electrode and data line;
etching the doped semiconductor layer film and the source/drain metallic film at the photoresist-completely-removed region to form patterns comprising the doped semiconductor layer, the source electrode, the drain electrode and the data line; and
removing the photoresist at the photoresist-completely-retained region.

3. The method according to claim 1, further comprising forming a storage electrode while the source electrode, the drain electrode and the data line are formed.

4. The method according to claim 2, further comprising forming a storage electrode while the source electrode, the drain electrode and the data line are formed.

5. The method according to claim 1, further comprising forming a storage electrode while the semiconductor layer, the gate insulating layer, the gate electrode and the gate line are formed.

6. The method according to claim 2, further comprising forming a storage electrode while the semiconductor layer, the gate insulating layer, the gate electrode and the gate line are formed.

7. The method according to claim 1, wherein the forming of patterns comprising the semiconductor layer, the gate electrode and the gate line by the patterning process comprising:
coating photoresist on the gate metallic film;
exposing and developing the photoresist with a mask to form a photoresist pattern comprising a photoresist-completely-retained region and a photoresist-completely-removed region, wherein the photoresist-completely-retained region corresponds to patterns of the gate electrode and the gate line;
etching the gate metallic film, the gate insulating layer film and the semiconductor layer film at the photoresist-completely-removed region to form patterns comprising the semiconductor layer, the gate insulating layer, the gate electrode and the gate line; and
removing the photoresist at the photoresist-completely-retained region.

8. The method according to claim 2, wherein the forming of patterns comprising the semiconductor layer, the gate electrode and the gate line by the patterning process comprising:
coating photoresist on the gate metallic film;
exposing and developing the photoresist with a mask to form a photoresist pattern comprising a photoresist-completely-retained region and a photoresist-completely-removed region, wherein the photoresist-completely-retained region corresponds to patterns of the gate electrode and the gate line;
etching the gate metallic film, the gate insulating layer film and the semiconductor layer film at the photoresist-completely-removed region to form patterns comprising the semiconductor layer, the gate insulating layer, the gate electrode and the gate line; and
removing the photoresist at the photoresist-completely-retained region.

9. The method according to claim 1, wherein the forming of patterns comprising the gate protection layer and the through hole by the patterning process comprising:
coating photoresist on the gate protection layer film;
exposing and developing the photoresist with a mask to form a photoresist pattern comprising a photoresist-completely-removed region and a photoresist-completely-removed region, the photoresist-completely-removed region corresponds to the through hole;
etching the gate protection layer film at the photoresist-completely-removed region to form patterns comprising the gate protection layer and the through hole; and
removing the photoresist at the photoresist-completely-retained region.

10. The method according to claim 1, wherein, the forming of patterns comprising the pixel electrode by the patterning process comprising:
coating photoresist on the pixel electrode film;
exposing and developing the photoresist with a mask to form a photoresist pattern comprising a photoresist-completely-removed region and a photoresist-completely-removed region, the photoresist-completely-retained region corresponds to the region comprising the pixel electrode;
etching the pixel electrode film at the photoresist-completely-removed region to form patterns comprising the pixel electrode; and
removing the photoresist at the photoresist-completely-retained region.

11. An array substrate, comprising a first base substrate having gate lines and data lines formed thereon, the gate lines and the data lines crossing with each other to surround and define pixel units, each pixel unit comprising a TFT switch and a pixel electrode, the TFT switch comprising a gate electrode, a source electrode, a drain electrode and a semiconductor layer; wherein:
the source electrode, the drain electrode and the data line are formed on the first base substrate;
the semiconductor layer comprises a first portion disposed corresponding to the gate electrode and formed between the source electrode and the drain electrode and connected to the source electrode and the drain electrode, and a second portion disposed corresponding to the gate line;
the gate insulating layer is formed on the semiconductor layer;
the gate electrode and the gate line are formed on the gate insulating layer, and the semiconductor layer, the gate insulating layer, the gate electrode and the gate line are synchronously formed;
the gate protection layer is formed over the gate electrode; and
the pixel electrode is connected to the drain electrode through the through hole penetrating the gate protection layer.

12. The array substrate according to claim 11, further comprising a doped semiconductor layer; the doped semiconductor layer is formed on the source electrode, the drain electrode and the data line; the semiconductor layer is formed on the doped semiconductor, and the first portion of the semiconductor layer is electrically connected to the source electrode and the drain electrode through the doped semiconductor layer, respectively;
the through hole penetrates the gate protection layer and the doped semiconductor layer.

13. The array substrate according to claim 11, further comprising a storage electrode disposed at a same level and in a same step as the source electrode, the drain electrode and the data line.

14. The array substrate according to claim 12, further comprising a storage electrode disposed at a same level and in a same step as the source electrode, the drain electrode and the data line.

15. The array substrate according to claim 11, further comprises a storage electrode disposed at a same level and in a same step as the gate electrode and the gate line.

16. The array substrate according to claim 12, further comprises a storage electrode disposed at a same level and in a same step as the gate electrode and the gate line.

17. An electron paper display, comprising the array substrate according to claim 11 and an upper substrate disposed oppositely to the array substrate with display medium interposed therebetween.

18. The electron paper display according to claim 17, wherein the upper substrate comprises a second base substrate;
the second base substrate has a common electrode, color resin and a black matrix formed thereon, or the second base substrate has a common electrode formed thereon.
